(19) United States
(12) Patent Application Publication
(10) Pub. No.: US 2020/0251636 A1
(43) Pub. Date: Aug. 6, 2020

(54) CHRISTMAS LIGHT AND STRAIGHT-PIN LED BEAD

(71) Applicant: Xinguo Zhou, Linhai City (CN)

(72) Inventor: Xinguo Zhou, Linhai City (CN)

(21) Appl. No.: 16/264,691

(22) Filed: Feb. 1, 2019

(51) Int. Cl. H01L 33/62; H01L 33/56; H01L 33/50

(52) U.S. Cl. CPC H01L 33/62; H01L 33/56; H01L 33/507; H01L 33/647; H01L 2933/005; H01L 2933/0041; H01L 2933/0066

(57) ABSTRACT

A straight-pin LED bead includes an SMD LED, which includes an LED chip, a first flat lead frame, a second flat lead frame, and a first encapsulation structure that houses the LED chip and fixes the first and second flat lead frames. The LED bead further includes a first terminal pin electrically connected with the first flat lead frame, a second terminal pin electrically connected with the second flat lead frame, and a second encapsulation structure that houses the first encapsulation structure and fixes the first terminal pin, the second terminal pin. The straight-pin LED bead uses a sorted SMD LED as a light source so that the straight-pin LED bead so obtained has excellent homogeneity and the loss of resin and first and second terminal pins used are reduced. The SMD LED is directly connected to the first and terminal pins to enhance heat dissipation.

### (a) TECHNICAL FIELD OF THE INVENTION

The present invention relates to the field of lighting, and more particularly to a lighting fixture, a straight-pin light-emitting diode (LED) bead, and a manufacturing method thereof.

### (b) DESCRIPTION OF THE PRIOR ART

A light-emitting diode (abbreviated as LED) is a novel solid-state light source. Born in the 60s of the twentieth century, Lossen.o.w found light emission in an impurity P-N junction in 1923 in study of semiconductor SiC and developed light-emitting diode, which has been not paid attention to. With the quick progress of the electronic industry, the display technology got increasing attention of people in the 60s. The advantages of LEDs are long service life (>100,000 Hrs.), low driving voltage (1.8-4.5V), low power consumption (40-1000 mW), being a relatively cold light source (small radiation), high-speed lighting (time constant being 10-7 to 10-9 S), eliminating potential lighting effect, being small in size, multiple colors, excellent resistance to vibration (completely solid packaging and being not readily broken), excellent monochromacy (emission wavelength being stable), and being green and free of pollution.

Referring to FIG. 1, Chinese Utility Model CN1883057 (Applicant: Nichia Corporation, and Inventors: Suguru Takashima, Masatoshi Kameshima, Hiroto Tamaki, Junju Takeichi, Yoshinori Murazaki, and Shinpei Minoshita) discloses a light-emitting device (a straight-pin LED bead), comprising a light emitting element 10 that emits ultraviolet ray, a cathode-side lead frame 13a (the first terminal pin) having a cup for placing the light emitting element 10 therein, an anode-side lead frame 13b (the second terminal pin) provided apart from the lead frame 13a, a coating member 12 (the first encapsulation structure) that includes a fluorescent material 11 provided in the cup of the lead frame 13a, and a transparent molding member 15 (the second encapsulation structure) that covers the entire device, while a plurality of fluorescent materials of indirect transition type are used for the fluorescent material 11.

Further, a positive electrode 3 of the light emitting element 10 is connected with a conductive wire 14 to the lead frame 13b, and a negative electrode 4 of the light emitting element 10 is connected with a conductive wire 14 to the lead frame 13a, while the light emitting element 10, the conductive wire 14, the cup of the lead frame 13a, and a tip of the lead frame 13b are covered by the transparent molding member 15.

The light-emitting device is manufactured as follows:

Firstly, the light emitting element 10 is soldered (die-bonded) face-up to the cup of the lead frame 13a by a die bonder. After die bonding, the lead frame 13 is transferred onto a wire bonder and the negative electrode 4 of the light emitting element is wire-bonded with a gold wire (electrically conductive wire) onto the upper edge of the cup of the lead frame 13a, and the positive electrode 3 is wire-bonded to the other lead frame 13b. Then, transfer is made onto a molding apparatus, and the cup of the lead frame 13a is filled with the fluorescent material 11 and the coating member 12 by a dispenser of the molding apparatus. The fluorescent material 11 and the coating member 12 are mixed uniformly in a predetermined proportion in advance before filling Color of light emitting from the light-emitting device is determined mainly by the color of light emitted by the plurality of fluorescent materials. After filling in the fluorescent material 11 and the coating member 12, the lead frame 13 is immersed in a mold frame that is filled with the resin to make the molding member 15, and the mold frame is removed and the resin is cured to harden, so as to make the bullet-shaped light-emitting device as shown in FIG. 1.

Referring to FIGS. 2 and 3, Chinese Utility Model CN106449937A (Applicant: Nichia Corporation, and Inventor: Wakaki) discloses a light emitting device 100 (SMD LED), which includes: a base body 101 provided with a recess S defined by a bottom surface and a side surface, and a pair of conductive members 102 whose upper surfaces are exposed at the bottom surface of the recess S. The conductive members 102 are disposed so that its lower surface provides an outer surface of the light emitting device 100, and thus together with the base body 101, constitute a part of the lower surface of the light emitting device 100. In the recess S, a light emitting element 103 (LED chip) is mounted by using a bonding member (not shown) and is electrically connected to the respective conductive members 102 by a conductive wire 105. Further, an optically transmissive sealing member 104 (first encapsulation structure) is disposed in the recess S to cover the light emitting element 103 or the like.

The method of manufacturing the light emitting device is as follows:

First, a support substrate formed from a metal plate is prepared. Next, a base body capable of reflecting light from the light emitting element is formed between conductive members. Next, using a bonding member, a light emitting element is bonded on the bottom surface in the recess of the base body and is electrically connected to each conductive member using a conductive wire. Thereafter, a sealing member containing an optically transmissive resin is filled in the recess. An aggregate of the light emitting devices is obtained by curing the sealing member, and then the support substrate is removed from the aggregate. Finally, the side wall between the recesses is cut into individual chips, and thus the light emitting device provided with a single recess as shown in FIG. 1 is obtained.

Often, due to terminal pins of a straight-pin LED bead being slender, molding of the terminal pins requires high accuracy. In automatic production, due to influence of progress of making the terminal pins, particularly the cup of 13a, the straight-pin LEDs so formed suffers poor homogeneity of color and brightness. An SMD LED adopts lead frames that are generally a plate like structure that is wide and short so that there is no need for arrangement of a cup configuration on the lead frame. The lead frame adopted in the SMD LED has low requirement for accuracy and the SMD LEDs so manufactured show excellent homogeneity.

However, in the known techniques, it is inevitable that inferior quality products and deviations (in respect of color and brightness) may occur in the manufacturing process of the straight-pin LED bead. The inferior quality products would lead to loss of the manufacturers in respect of resin used in a second encapsulation structure and first and second terminal pins.

### SUMMARY OF THE INVENTION

Objectives of the present invention are to provide a straight-pin light-emitting diode (LED) bead, which provides excellent homogeneity of the straight-pin LED beads manufactured in the production of the straight-pin LED bead and reduces the loss of resin and first terminal pins and second terminal pins used in the production.

Objectives of the present invention are also to provide a lighting fixture, which uses the straight-pin LED bead as a light source so as to reduce the loss of resin and first terminal pins and second terminal pins used in production.

Objectives of the present invention are further to provide a straight-pin LED bead manufacturing process, through which straight-pin LED beads so manufactured show excellent homogeneity and loss of resin and first terminal pins and second terminal pins used is reduced.

To achieve the above advantages, the present invention provides a straight-pin light-emitting diode (LED) bead, which comprises a surface-mount-device (SMD) LED. The SMD LED comprises an LED chip, a first flat lead frame, a second flat lead frame, and a first encapsulation structure that houses the LED chip and fixes the first flat lead frame and the second flat lead frame. The LED bead further comprises a first terminal pin electrically connected to the first flat lead frame, a second terminal pin electrically connected to the second flat lead frame, and a second encapsulation structure that houses the first encapsulation structure and fixes the first terminal pin and the second terminal pin.

In an embodiment of the present invention, the first flat lead frame is attached to an end face of an upper end of the first terminal pin and the second flat lead frame is attached to an end face of an upper end of the second terminal pin.

In an embodiment of the present invention, the first flat lead frame is attached to a side face of an upper end of the first terminal pin and the second flat lead frame is attached to a side face of an upper end of the second terminal pin.

In an embodiment of the present invention, a lighting fixture comprising the straight-pin LED bead comprises the following steps:

A, connecting a first flat lead frame and a second flat lead frame of a sorted SMD LED to a first terminal pin bar and a second terminal pin bar of an LED bracing board;

B, covering second package resin on an outside of a first encapsulation structure to form an uncured second encapsulation structure;

C, heating and curing a surface of the uncured second encapsulation structure;

D, cutting and trimming a connection bar of the first terminal pin bar and the second terminal pin bar of the LED bracing board to form a first terminal pin and a second terminal pin, so as to form a straight-pin LED bead.

In an embodiment of the present invention, Step E comprises: A1, coating solder paste on the first flat lead frame and/or the first terminal pin bar, and on the second flat lead frame and/or the second terminal pin bar; A2, flat positioning the first flat lead frame on the first terminal pin bar and flat positioning the second flat lead frame on the second terminal pin bar; A3, heating and melting the solder paste; A4, increasing a pressure between the first flat lead frame and the first terminal pin bar and between the second flat lead frame and the second terminal pin bar; A5, cooling down the melted solder paste to have the first flat lead frame and the first terminal pin bar bonded and fixed and the second flat lead frame and the second terminal pin bar bonded and fixed.

In an embodiment of the present invention, the second package resin comprises one or more selected from epoxy resin, organic silicon and organic silicon modified epoxy resin.

In an embodiment of the present invention, the sorted SMD LED of Step A is obtained with the following steps:

S101, electrically connecting two electrodes of an LED chip to a first flat lead frame and a second flat lead frame, respectively;

S102, covering first package resin on an outside of the LED chip to form an uncured first encapsulation structure;

S103, heating and completely curing the uncured first encapsulation structure, so as to have the first encapsulation structure fix the first flat lead frame and the second flat lead frame to form an SMD LED;

S104, classifying the SMD LED;

In an embodiment of the present invention, the first package resin is formed by homogeneously mixing fluorescent powders with encapsulation resin.

In an embodiment of the present invention, Step S104 comprises: classifying multiple ones of the SMD LED according to color temperature and/or brightness to obtain multiple groups of sorted SMD LED.

In the lighting fixture, the straight-pin LED bead, and the manufacturing process according to the present invention, the straight-pin LED bead uses sorted SMD LED(s) as a light source to provide excellent homogeneity of the straight-pin LED beads with reduced loss of resin and the first terminal pin and the second terminal pin during manufacturing. In the present invention, the SMD LED is directly connected to the first terminal pin and the second terminal pin and the first terminal pin and the second terminal pin provide an effect of enhancing heat dissipation so that the straight-pin LED bead so formed may have an extended lifespan and reduced light deterioration.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view showing a prior art straight-pin light-emitting diode (LED) bead.

FIG. 2 is a schematic view showing a prior art surface-mount-device (SMD) LED.

FIG. 3 is a cross-sectional view of the SMD LED of FIG. 2.

FIG. 4 is a schematic view illustrating a straight-pin LED bead according to a first embodiment of the present invention.

FIG. 5 is a schematic view showing an SMD LED of the straight-pin LED bead shown in FIG. 4.

FIG. 6 is a schematic view showing a first flat lead frame and a second flat lead frame of the SMD LED shown in FIG. 5.

FIG. 7 is a schematic view showing a first terminal pin and a second terminal pin of the straight-pin LED bead shown in FIG. 4.

FIG. 8 is a schematic view showing a condition before the SMD LED and the first and second terminal pins are connected in a manufacturing process of the straight-pin LED bead according to the first embodiment of the present invention.

FIG. 9 is a schematic view showing a condition after the SMD LED and the first and second terminal pins shown in FIG. 6 are connected in the manufacturing process of the straight-pin LED bead.

FIG. 10 is a schematic view showing a condition after the SMD LED shown in FIG. 9 is encapsulated with the second encapsulation structure in the manufacturing process of the straight-pin LED bead after the condition.

FIG. 11 is a schematic view showing a condition after the first and second terminal pins shown in FIG. 10 are subjected to cutting in the manufacturing process of the straight-pin LED bead.

FIG. 12 is a schematic view showing a condition before the first flat lead frame and the LED chip of the SMD LED of FIG. 1 are connected.

FIG. 13 is a schematic view showing a condition after the first flat lead frame and the LED chip the SMD LED shown in FIG. 12 are connected.

FIG. 14 is a schematic view showing a condition after the SMD LED shown in FIG. 13 is encapsulated with the first encapsulation structure.

FIG. 15 is a schematic view showing a condition after SMD LEDs and first and second terminal pins are connected in a manufacturing process of a straight-pin LED bead according to a second embodiment of the present invention.

FIG. 16 is a schematic view showing a condition after SMD LEDs and first and second terminal pins are connected in a manufacturing process of a straight-pin LED bead according to a third embodiment of the present invention.

FIG. 17 is a schematic view showing a condition after SMD LEDs and first and second terminal pins are connected in a manufacturing process of a straight-pin LED bead according to a fourth embodiment of the present invention.

FIG. 18 is a partly enlarged view of FIG. 8.

FIG. 19 is a partly enlarged view of FIG. 15.

FIG. 20 is a partly enlarged view of FIG. 16.

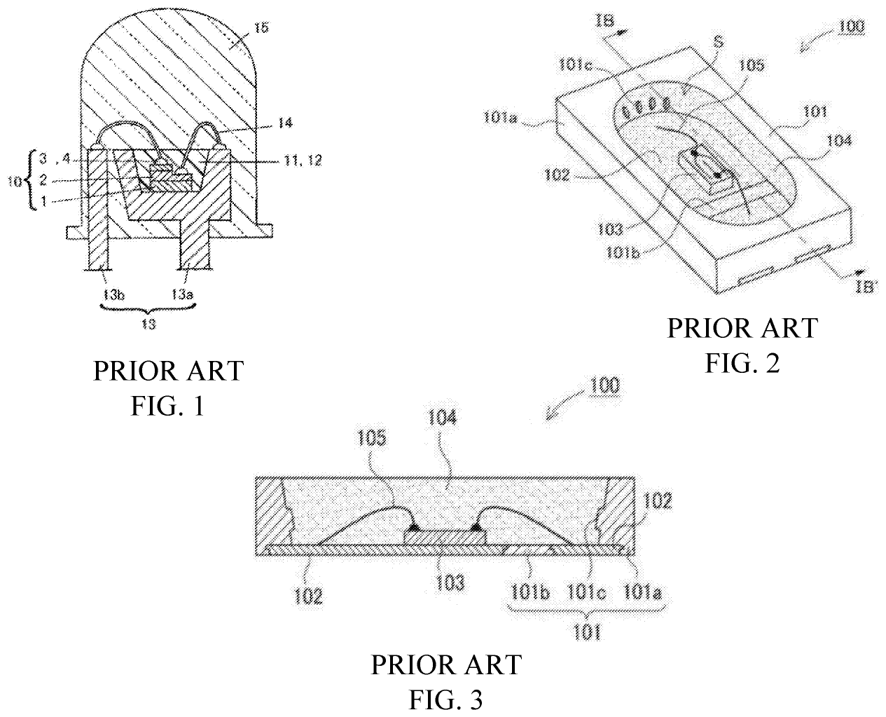

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

To further expound the technical solution that the present invention adopts to achieve preset purposes of this invention, and the advantages thereof, a detailed description concerning embodiments, structures, features, and advantages that are provided in the present invention will be provided with reference to the attached drawings and preferred embodiments.

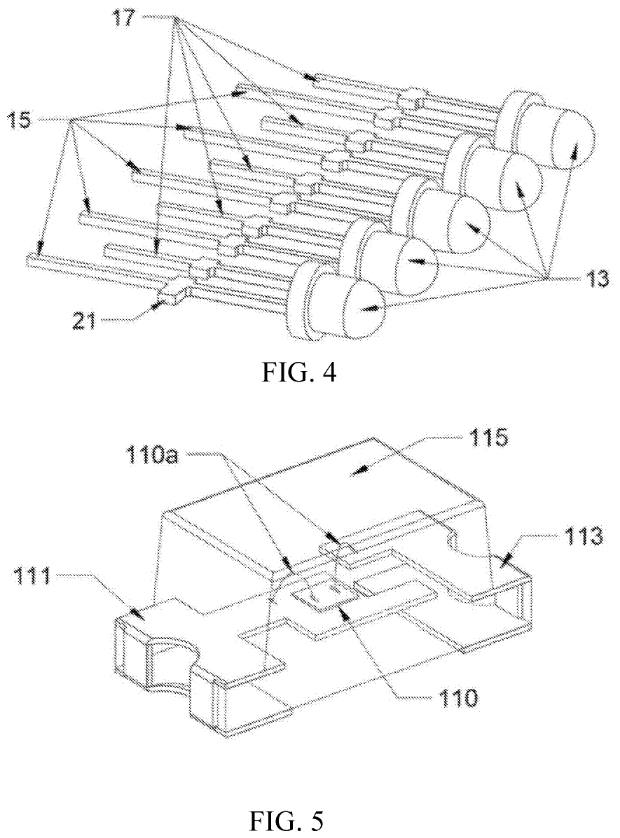

FIG. 4 is a schematic view illustrating a straight-pin light-emitting diode (LED) bead according to a first embodiment of the present invention. Referring to FIG. 4, the straight-pin LED bead 10 according to the first embodiment of the present invention comprises a surface-mount-device (SMD) LED 11, a second encapsulation structure 13, a first terminal pin 15, and a second terminal pin 17. The SMD LED 11 is completely housed inside the second encapsulation structure 13; the first terminal pin 15 and the second terminal pin 17 having upper ends housed in the second encapsulation structure 13; the first terminal pin 15 and the second terminal pin 17 have a gap therebetween; end faces of the upper ends of the first terminal pin 15 and the second terminal pin 17 are respectively mounted to a first flat lead frame 111 and second flat lead frame 113 of the SMD LED 11.

FIG. 5 is a schematic view showing the SMD LED of the straight-pin LED bead shown in FIG. 4. Referring to FIG. 5, the SMD LED 11 can be a 0603 SMD LED. The SMD LED comprises an LED chip 110, leads 110a, the first flat lead frame 111, the second flat lead frame 113 and a first encapsulation structure 115 that encapsulates the LED chip 110 and fixes the first flat lead frame 111 and the second flat lead frame 113.

In other embodiments, the SMD LED may be an SMD LED of a different specification, such as 1206, 2810, 3020, 3528, and 5050 SMD LEDs. The SMD LED may be of a color that is selected as one of monochrome, dual-colored, or full-color.

The LED chip 110 is a primary ingredient component of the SMD LED 11 and SMD LED relies on the LED chip 110 for emission of light. The LED chip 110 is provided with a positive terminal and a negative terminal on a top surface thereof The LED chip 110 is mounted and fixed on the first flat lead frame 111 by silver paste 110b. The silver paste 110b can be a kind of non-conductive silver paste.

The leads 110a electrically connect the positive and negative terminals of the LED chip 110 to the first flat lead frame 111 and the second flat lead frame 113, respectively.

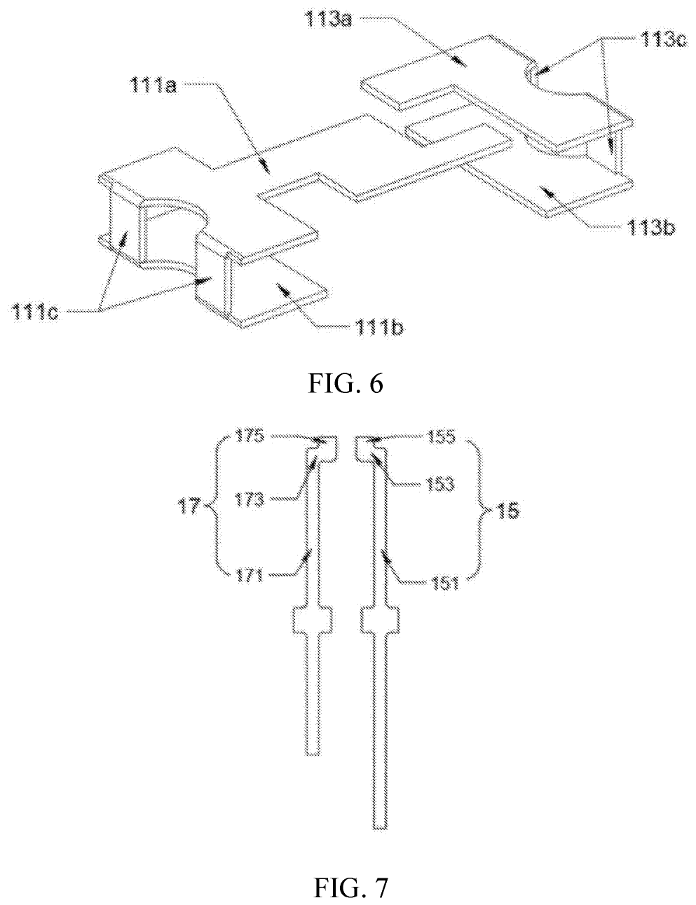

FIG. 6 is a schematic view showing the first flat lead frame and the second flat lead frame of the SMD LED shown in FIG. 5. Referring to FIG. 6, the first flat lead frame 111 comprises an first upper plate 111a, a first lower plate 111b, and a first connection plate 111c that connects the first upper plate 111a and the first lower plate 111b to each other. The second flat lead frame 113 comprises a second upper plate 113a, a second lower plate 113b, and a second connection plate 113c that connects the second upper plate 113a and the second lower plate 113b to each other.

The second encapsulation structure 13 houses and encloses the first encapsulation structure 115 and fixes the first terminal pin 15 and the second terminal pin 17 in position. The second encapsulation structure 13 is made of a light transmitting material such as epoxy resin, organic silicon, and organic silicon modified epoxy resin.

FIG. 7 is a schematic view showing the first terminal pin and the second terminal pin of the straight-pin LED bead shown in FIG. 4. FIG. 5 is a schematic view showing a bracing board 20 that is used to make the first terminal pin and the second terminal pin. Referring to FIGS. 4 and 5, the first terminal pin 15 and the second terminal pin 17 are formed by first stamping a metal plate to make a bracing board 20, which is then subjected to foot cutting or trimming.

The bracing board 20 comprises a central connection bar 21 and bottom connection plate 23, which are arranged horizontally, and multiple first terminal pin bars 25 and second terminal pin bars 27 that are arranged vertically arranged at intervals. The central connection bar 21 and the bottom connection plate 23 function to keep relative positions of the first terminal pin bars 25 and the second terminal pin bars 27 and to prevent the first terminal pin bars 25 and the second terminal pin bars 27 from getting deformed.

The first terminal pin 15 and the second terminal pin 17 are of structures that are similar. The first terminal pin 15 comprises a bar-like first leg section 151, a first connection section 153, and a first upper end section 155. The first upper end section 155 and the first connection section 153 have cross-section areas that are greater than a cross-sectional area of the first leg section 151. The first upper end section 155 has an upper end face that is a surface laid flat on and mounted to the first flat lead frame. As such, when the LED chip emits light, heat is conducted, in a high efficiency, from the first flat lead frame, which is made of a metal, or the first encapsulation structure, the first upper end section 155, and the first connection section 153 to the first leg section 151 to dissipate in air in order to prevent an excessively high temperature of the LED chip.

The second terminal pin 17 similarly comprises a bar-like second leg section 151, a second connection section 153, and a second upper end section 155.

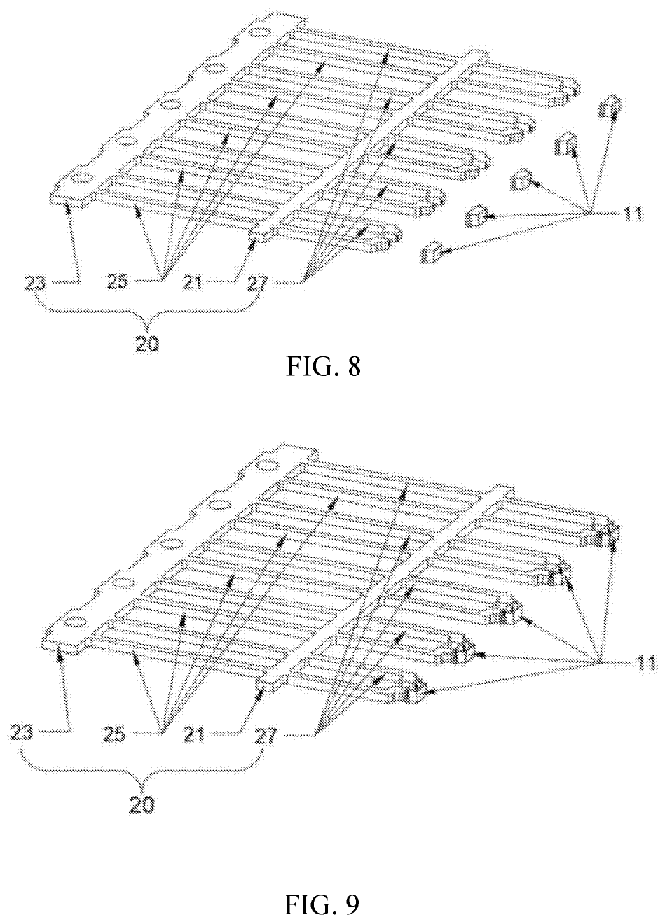

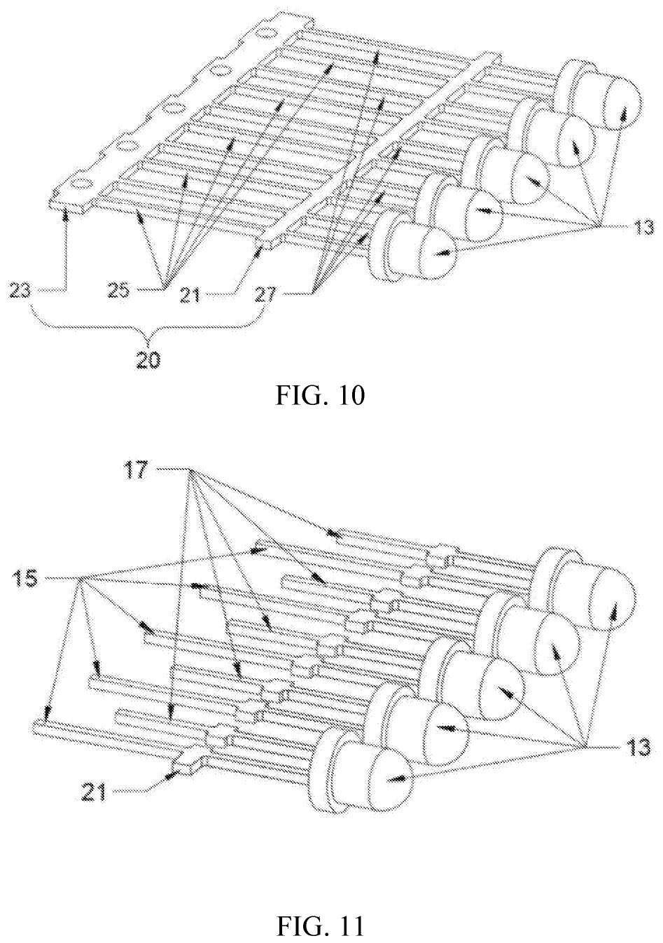

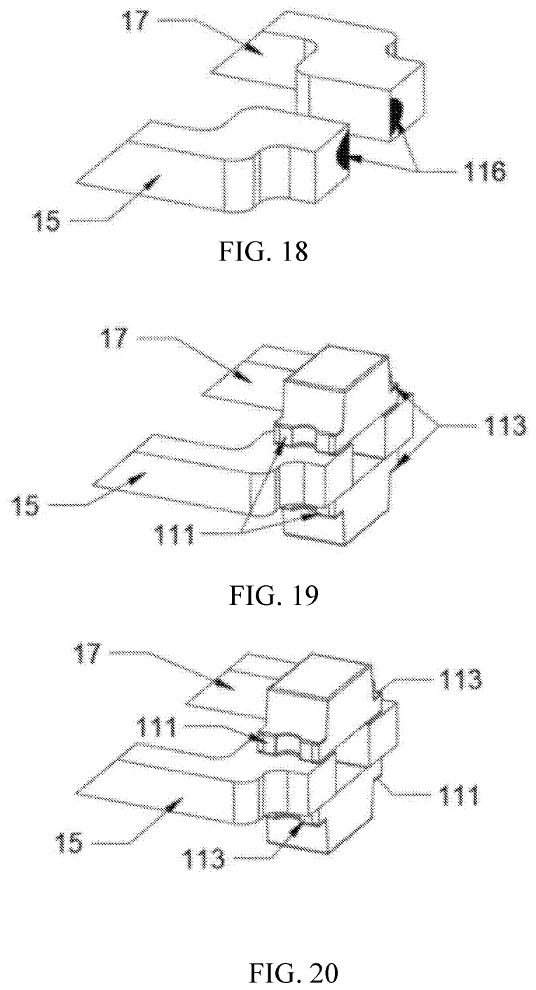

FIG. 8 is a schematic view showing a condition before the SMD LED and the first and second terminal pins are connected in a manufacturing process of the straight-pin LED bead according to the first embodiment of the present invention. FIG. 9 is a schematic view showing a condition after the SMD LED and the first and second terminal pins shown in FIG. 6 are connected in the manufacturing process of the straight-pin LED bead. FIG. 10 is a schematic view showing a condition after the SMD LED shown in FIG. 9 is encapsulated with the second encapsulation structure in the manufacturing process of the straight-pin LED bead after the condition. FIG. 11 is a schematic view showing a condition after the first and second terminal pins shown in FIG. 10 are subjected to cutting in the manufacturing process of the straight-pin LED bead. Referring to FIGS. 8, 9, 10, 11, and 18, in the instant embodiment, the straight-pin LED bead manufacturing process comprises the following steps:

E, connecting first flat lead frames 111 and second flat lead frames 113 of sorted SMD LEDs 11 to first terminal pin bars 25 and second terminal pin bars 27 of a bracing board 20, respectively;

F, covering second package resin outside the first encapsulation structure 115 to form an uncured second encapsulation structure 13;

G, heating and thus curing a surface of the uncured second encapsulation structure 13;

D, cutting and trimming the first terminal pin bars 25, the second terminal pin bars 27, the first connection bar, and the second connection bar of the bracing board 20 to form first terminal pins 15 and second terminal pins 17, so as to form straight-pin LED beads 10.

Further, in Step A, the first flat lead frame 111 is positioned flat on and attached to an end face of an upper end of the first terminal pin 15 and the second flat lead frame 113 is positioned flat on and flat attached to an end face of an upper end of the second terminal pin 17. The SMD LED 11 is directly connected to the first terminal pin 15 and the second terminal pin 17 and the first terminal pin 15 and the second terminal pin 17 provide an effect of enhancing heat dissipation so that the straight-pin LED bead 10 so formed may have an extended lifespan and reduced light deterioration.

Further, Step A comprises:

A1, coating solder paste 116 on the first flat lead frame 111 and/or the first terminal pin bars 25, and on the second flat lead frame 113 and/or the second terminal pin bars 27;

A2, flat positioning the first flat lead frame 111 on the first terminal pin bar 25 and flat positioning the second flat lead frame 113 on the second terminal pin bar 27;

A3, heating and melting the solder paste 116;

A4, increasing a pressure between the first flat lead frame 111 and the first terminal pin bar 25 and between the second flat lead frame 113 and the second terminal pin bar 27;

A5, cooling down the melted solder paste 116 to have the first flat lead frame 111 and the first terminal pin bar 25 bonded and fixed and the second flat lead frame 113 and the second terminal pin bar 27 bonded and fixed.

In the process, Step B uses second package resin that is one or more selected from epoxy resin, organic silicon and organic silicon modified epoxy resin.

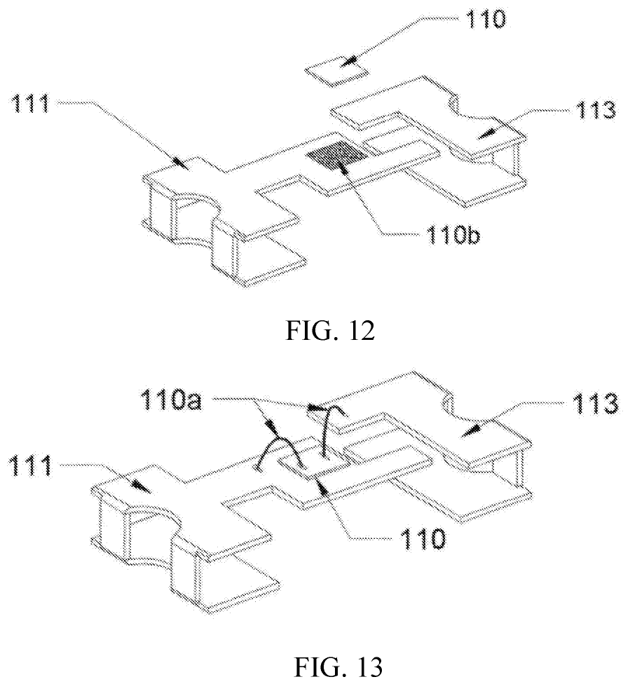

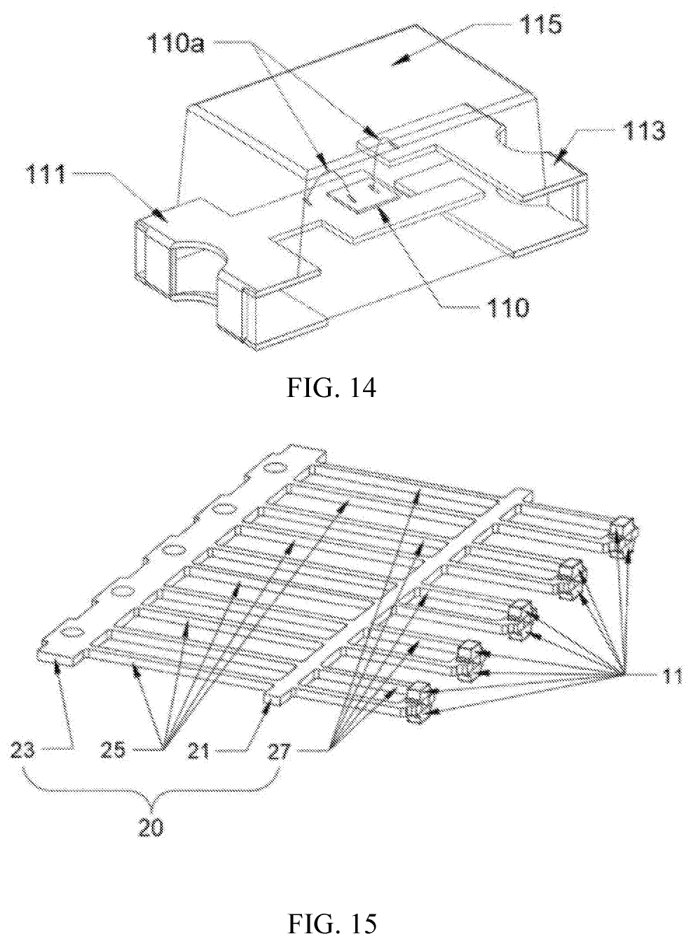

FIG. 12 is a schematic view showing a condition before the first flat lead frame and the LED chip of the SMD LED of FIG. 1 are connected; FIG. 13 is a schematic view showing a condition after the first flat lead frame and the LED chip the SMD LED shown in FIG. 12 are connected; and FIG. 14 is a schematic view showing a condition after the SMD LED shown in FIG. 13 is encapsulated with the first encapsulation structure. Referring to FIGS. 12, 13, and 14, the sorted SMD LEDs 11 of Step A are obtained with the following steps:

S101, electrically connecting two electrodes of an LED chip 110 to a first flat lead frame 111 and a second flat lead frame 113, respectively;

S102, covering first package resin on an outside of the LED chip 110 to form an uncured first encapsulation structure 115;

S103, heating and completely curing the uncured first encapsulation structure 115, so as to have the first encapsulation structure 115 fix the first flat lead frame 111 and the second flat lead frame 113 to form an SMD LED 11;

S104, classifying multiple ones of the SMD LED 11 so obtained according to color temperature and/or brightness to obtain multiple groups of sorted SMD LEDs 11;

wherein the first package resin of Step S102 is formed by homogeneously mixing fluorescent powders with encapsulation resin.

FIG. 15 is a schematic view showing a condition after SMD LEDs and first and second terminal pins are connected in a manufacturing process of a straight-pin LED bead according to a second embodiment of the present invention. Referring to FIGS. 15 and 19, in the instant embodiment, two SMD LEDs are respectively arranged at two opposite sides of a first terminal pin and a second terminal pin, with first flat lead frames 111 being positioned flat on and attached to a side face of an upper end of the first terminal pin 15 and second flat lead frames 113 being positioned flat on and attached to a side face of an upper end of the second terminal pin 17.

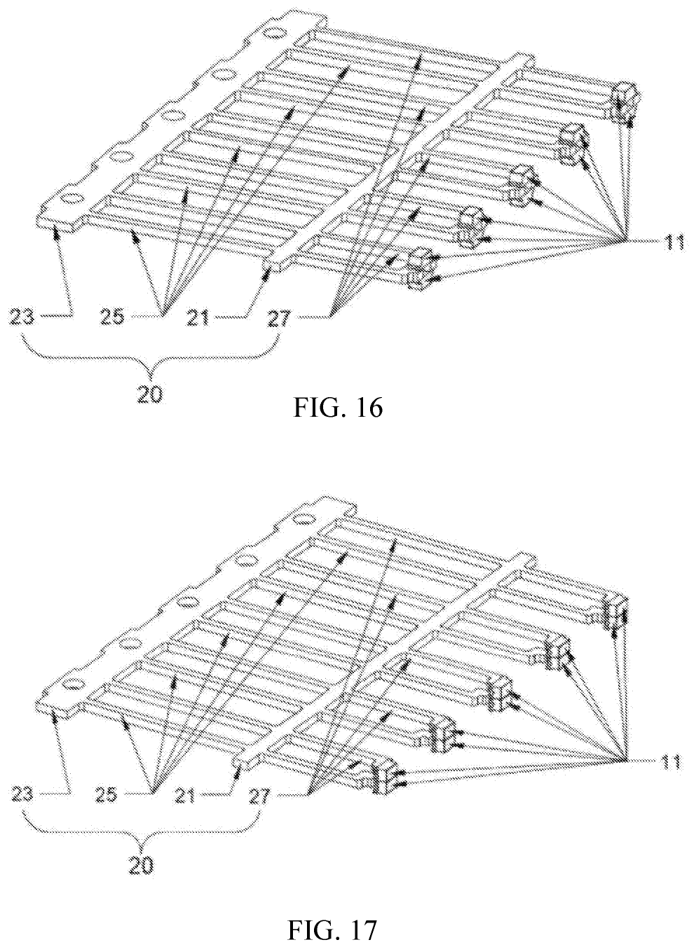

FIG. 16 is a schematic view showing a condition after SMD LEDs and first and second terminal pins are connected in a manufacturing process of a straight-pin LED bead according to a third embodiment of the present invention. Referring to FIGS. 16 and 20, in the instant embodiment, two SMD LEDs are respectively arranged at two opposite sides of a first terminal pin and a second terminal pin. A first flat lead frame 111 of one of the SMD LEDs is positioned flat on and attached to a side face of an upper end of the first terminal pin 15 and a second flat lead frame 113 is positioned flat on and attached to a side face of an upper end of the second terminal pin 17; and a first flat lead frame 111 of the other one of the SMD LEDs is positioned flat on and attached to a side face of the upper end of the second terminal pin 17 and a second flat lead frame 113 is positioned flat on and attached to a side face of the upper end of the first terminal pin 15.

FIG. 17 is a schematic view showing a condition after SMD LEDs and first and second terminal pins are connected in a manufacturing process of a straight-pin LED bead according to a fourth embodiment of the present invention. Referring to FIG. 17, in the instant embodiment, two SMD LEDs are respectively arranged on end faces of upper ends of a first terminal pin and second terminal pin. A first flat lead frame 111 of one of the SMD LED is positioned flat on and attached to the end face of the upper end of the first terminal pin 15 and a second flat lead frame 113 is positioned flat on and attached to the end face of the upper end of the second terminal pin 17; the first flat lead frame 111 of the other one of the SMD LEDs is positioned flat on and attached to the end face of the upper end of the second terminal pin 17 and a second flat lead frame 113 is positioned flat on and attached to the end face of the upper end of the first terminal pin 15.

In the third and fourth embodiments of the present invention, the straight-pin LED bead comprises two SMD LEDs that are connected in parallel but in opposite directions, meaning operation of the LED chips are not constrained by the direction of electrical current.

The present invention also provides a lighting fixture that comprises one of the straight-pin LED beads described above.

In the lighting fixture, the straight-pin LED bead, and the manufacturing process according to the present invention, the straight-pin LED bead uses sorted SMD LED(s) as a light source to provide excellent homogeneity of the straight-pin LED beads with reduced loss of resin and the first terminal pin and the second terminal pin during manufacturing. In the present invention, the SMD LED is directly connected to the first terminal pin and the second terminal pin and the first terminal pin and the second terminal pin provide an effect of enhancing heat dissipation so that the straight-pin LED bead so formed may have an extended lifespan and reduced light deterioration.

As shown in the following table, in the present invention, the SMD LED uses two flat lead frames, which are easy to make and show good stiffiiess and high accuracy so that SMD LEDs so formed show excellent homogeneity and high yield rate. Through further sorting of the SMD LEDs, the color temperature and brightness of the SMD LED so provided have better homogeneity in respect of color temperature and brightness, saving resin and lead frames used, and shortening overall curing time due to no need to waiting for completely curing of the first encapsulation. Further, the SMD LED is directly connected to the first terminal pin and the second terminal pin and the first terminal pin and the second terminal pin provide an effect of enhancing heat dissipation so that the straight-pin LED bead so formed may have an extended lifespan and reduced light deterioration.

According to calculation made by Applicant, the straight-pin LED bead proposed in this application has a cost that is lower than the prior art straight-pin LED beads of the same quality grade, and the manufacturing efficiency is higher, so that a prosperous future in the market can be expected.

| No. | Test Item | Test Data | Test Result | Note |
|---|---|---|---|---|
| 1 | electrical parameter | 3.0 V-3.2 V 20 mA | 3.0 V-3.2 V 20 mA | |
| 2 | deterioration degree | test current 15 mA | 10% | |
| | | 1000 hrs ≤ 10% | | |
| 3 | brightness | 3.0 V-3.2 V 20 mA | brightness 3.5 LM | |
| 4 | lifespan | arranged as a string for test | 45 no test, no dead bulb, no dead | |
| | | | group, no flashing | |
| 5 | light color | 2.6 V-3.2 V, 6 mA, 25 mA, | color and light brightness | |
| | | 20 mA | consistent | |

The above provides only preferred embodiments of the present invention and does not intend to impose constraints of any form to the present invention. Illustration of preferred embodiments, although provided above for disclosure of the present invention, is not intended to limit the present invention. Those skilled in the art may make use of the above-disclosed technical contents to elaborate equivalent embodiments through minor modifications or equivalent variations, without departing from the scope of the present invention. Those easy modifications, equivalent variations and changes that are made on the embodiments provided above according to the technical substantives of the present invention and do not depart from the technical contents of the present invention are considered belonging to the scope of the technical solution of the present invention.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A straight-pin light-emitting diode (LED) bead, comprising a surface-mount-device (SMD) LED, the SMD LED comprising an LED chip, a first flat lead frame, a second flat lead frame, and [symbol] the first encapsulation structure that houses the LED chip and fixes the first flat lead frame and the second flat lead frame, wherein the LED bead further comprises a first terminal pin electrically connected with the first flat lead frame, a second terminal pin electrically connected with the second flat lead frame, and a second encapsulation structure that houses the first encapsulation structure and fixes the first terminal pin and the second terminal pin.

2. The straight-pin LED bead according to claim 1, wherein the first flat lead frame is attached to an end face of an upper end of the first terminal pin and the second flat lead frame is attached to an end face of an upper end of the second terminal pin.

3. The straight-pin LED bead according to claim 1, wherein the first flat lead frame is attached to a side face of an upper end of the first terminal pin and the second flat lead frame is attached to a side face of an upper end of the second terminal pin.

4. The straight-pin LED bead according to claim 1, wherein the first flat lead frame and the first terminal pin are fixed through soldering with solder paste and the second flat lead frame and the second terminal pin are fixed through soldering with solder paste.

5. The straight-pin LED bead according to claim 1, wherein the first terminal pin comprises a bar-like first leg section, a first connection section, and a first upper end section, the first leg section and the first connection section having cross-sectional areas that are greater than a cross-sectional area of the first leg section.

6. The straight-pin LED bead according to claim 5, wherein the first upper end section has an upper end forming a surface to which the first flat lead frame is attached.

7. The straight-pin LED bead according to claim 1, wherein the second terminal pin comprises a bar-like second leg section, a second connection section, and a second upper end section, the second leg section and the second connection section having cross-sectional areas that are greater than a cross-sectional area of the second leg section.

8. The straight-pin LED bead according to claim 7, wherein the second upper end section has an upper end forming a surface to which the second flat lead frame is attached.

9. The straight-pin LED bead according to claim 1, wherein the second encapsulation structure is made of a light transmitting material.

10. A lighting fixture, comprising a straight-pin LED bead according to claim 1.

11. A lighting fixture, comprising a straight-pin LED bead according to claim 2.

12. A lighting fixture, comprising a straight-pin LED bead according to claim 3.

13. A lighting fixture, comprising a straight-pin LED bead according to claim 4.

14. A lighting fixture, comprising a straight-pin LED bead according to claim 5.

15. A lighting fixture, comprising a straight-pin LED bead according to claim 6.

16. A lighting fixture, comprising a straight-pin LED bead according to claim 7.

17. A lighting fixture, comprising a straight-pin LED bead according to claim 8.

18. A lighting fixture, comprising a straight-pin LED bead according to claim 9.
